(19) United States
(12) Patent Application Publication
(10) Pub. No.: US 2004/0197939 A1
(43) Pub. Date: Oct. 7, 2004

(54) Method and apparatus for sub-micron device fabrication

(76) Inventor: Corey M. Clark, Watauga, TX (US)

Correspondence Address: Thomas C. Wright, Gardere Wynne Sewell LLP, 3000 Thanksgiving Tower, Suite 3000, 1601 Elm Street, Dallas, TX, 75201-4767, US

(21) Appl. No.: 10/391,506

(22) Filed: Mar. 18, 2003

(51) Int. Cl. H01L 21/66

(52) U.S. Cl. 438/14

(57) ABSTRACT

The present invention provides a method and apparatus for the preparation of sub-micron features for use in solid-state electronic applications. Creation of a template by logical design to produce features of predetermined size and shape allows for the use of a variety of deposition methods to be used to create the sub-micron features.

### FIELD OF THE INVENTION

The present invention is directed generally to the field of semiconductor technology and specifically to a method and apparatus for fabricating sub-micron devices on semiconductor surfaces.

### BACKGROUND OF THE INVENTION

The success of semiconductor-based devices has resulted in large part from improvements in processing technology that have allowed for the placement of more and more individual components on the same sized semiconductor substrate. Current lithographic technology is unable to effectively produce features smaller than a 100 nm.

The consumer electronics industry has grown rapidly, based in large part on the continuing development of devices with an ever-increasing array of features. In order to continue the development of smaller and faster semiconductor based equipment it will be necessary that new techniques are developed to produce smaller features than is presently possible. Concomitant with the production of smaller features will be the need for the new techniques to be applicable to the mass production of semiconductor chips.

There is therefore a need for an improved method and apparatus for producing semiconductor features on substrates that are below 100 nanometers in size, with high throughput. The present invention fills such a need.

### SUMMARY OF THE INVENTION

The present invention provides a method and apparatus for the preparation of sub-micron features for use in solid-state electronic applications. Creation of a template by logical design to produce features of predetermined size and shape allows for the use of a variety of deposition methods to be used to create the sub-micron features.

In one form, the present invention provides a method for forming a template for use in fabricating sub-micron scale features that includes the steps of determining a pattern for a template and calculating the required thickness of a crystalline template substrate, having an upper surface and a lower surface, to produce the template pattern in the substrate. A mask is created corresponding to the pattern, and the mask is contacted with the upper surface of the crystalline template substrate. The upper surface of the crystalline substrate is then anisotropically etched with an etchant to produce a template with openings in the bottom surface of the substrate essentially corresponding with the pattern. The mask may be formed directly upon the upper surface of the substrate by way of photolithography, thus combining the steps of mask creation and contacting with the upper surface of the substrate.

In another form, the present invention provides a method of fabricating sub-micron scale features including the steps of determining a pattern for a template and calculating the required thickness of a crystalline template substrate, having an upper surface and a lower surface, to produce the template pattern in the substrate. A mask is created corresponding to the pattern, and the mask is contacted with the upper surface of the crystalline template substrate. The upper surface of the crystalline substrate is then anisotropically etched with an etchant to produce a template with openings in the bottom surface of the substrate essentially corresponding with the pattern. The template is aligned with a target, and material is deposited through the template to substantially reproduce the pattern on the surface of the target.

The present invention will allow for conventional fabrication equipment to be used to produce devices that surpass the current hurdle in device feature size. It may be integrated into conventional fabrication lines with only minor modifications to equipment, if any. The process of the present invention also has the capability to be compatible with mass production of sub-micron scale electronics using the same parallel fabrication process that is currently used in the semiconductor industry.

The present invention uses photolithography to create a template structure that may be used for fabricating nano-scale electronics. Any method of photolithography may be used, including traditional mask-type photolithography as well as maskless techniques. The process of the present invention defines structures such as squares and rectangles on smooth pre-thinned semiconductor substrates, such as silicon [100] for example, and is followed by an anisotropic etch completely through the semiconductor wafer. As the anisotropic etch continues through the wafer the predefined structures will be refined until they produce openings in the bottom side of the wafer corresponding to nano-scale dots or lines, e.g. nanowires.

### BRIEF DESCRIPTION OF THE FIGURES

For a complete understanding of the features and advantages of the present invention, reference is now made to the detailed description of the invention along with the accompanying drawings in which:

FIG. 1(a) is a perspective depiction of a template in accordance with the present invention;

FIG. 1(b) is a depiction of the upper surface of a template in accordance with the present invention;

FIG. 1(c) is a depiction of the lower surface of a template in accordance with the present invention;

FIG. 2 is a depiction of the lattice structure of elemental silicon;

FIG. 3 is a representation of different crystallographic planes in a silicon crystal;

FIG. 4 is a depiction of etch fronts that may be used in the fabrication of templates in accordance with the present invention;

FIG. 5 is a cross sectional view of an etched feature in a template in accordance with the present invention;

FIG. 6 is a depiction of the CMP process;

FIG. 7 is a depiction of an alignment technique in accordance with the present invention;

FIG. 8 depicts an interference pattern produced via projection through a template in accordance with the present invention; and

FIG. 9 depicts four examples of deposition techniques in accordance with the present invention.

### DETAILED DESCRIPTION OF THE INVENTION

The invention, as defined by the claims, may be better understood by reference to the following detailed description. The description is meant to be read with reference to the figures contained herein. This detailed description relates to examples of the claimed subject matter for illustrative purposes, and is in no way meant to limit the scope of the invention.

By thinning the wafer to a predetermined thickness the nano features can be fabricated at the point where the etch goes through the silicon wafer. This wafer may then be used as a template to create nano structures on a target substrate below it. With the template placed on top of a target substrate, deposition can occur and block the bonding of the impinging molecules on the target substrate everywhere except at the points where the nano structures have been defined. The defined structures can be placed on the template multiple times allowing for multiple devices to be created in parallel.

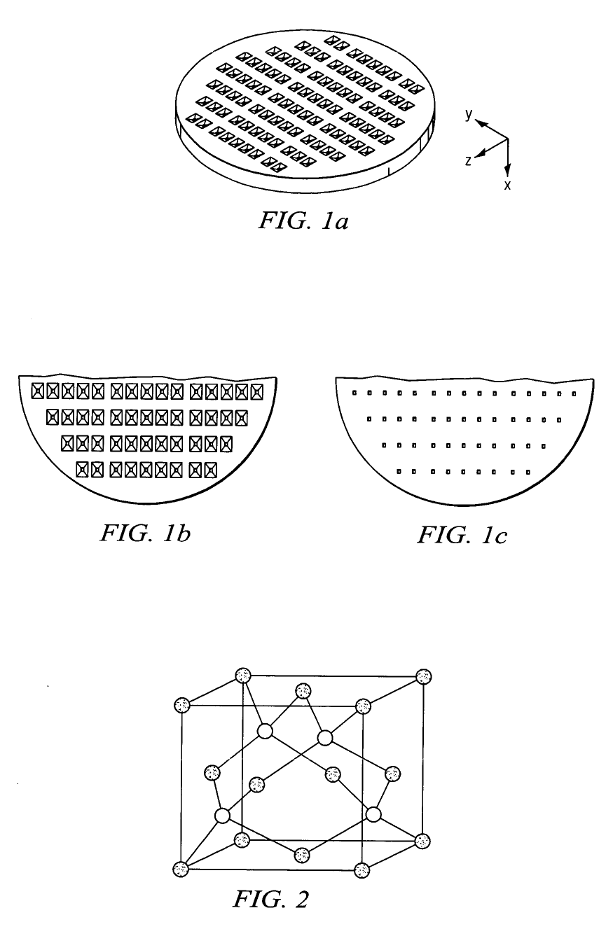

A template of the present invention, as previously described, consists of a semiconductor wafer patterned with holes or lines. The holes are actually truncated pyramids, and the lines are truncated V-grooves depending on the nano structure needed (nano dot or nanowire). The structure of a template in accordance with the present invention is shown in FIG. 1.

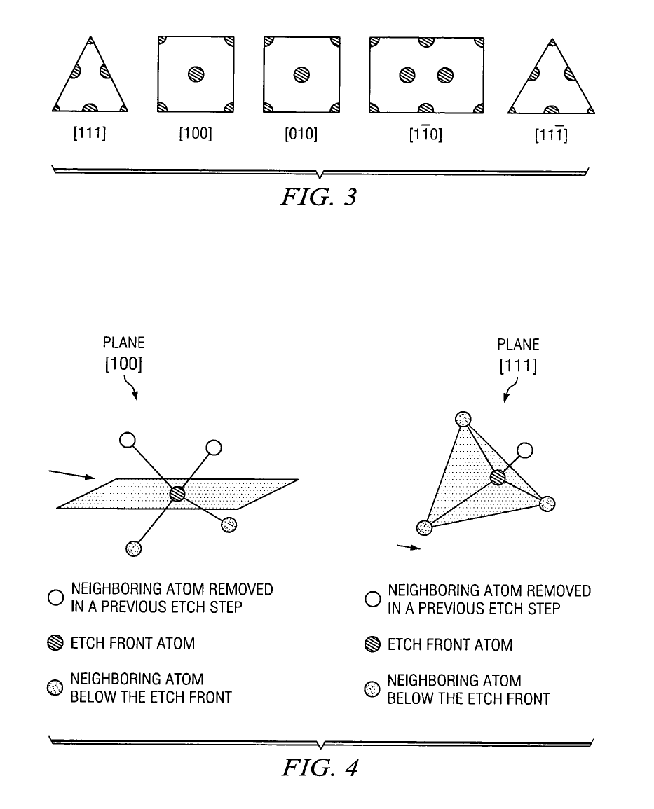

The fabrication of the grooves is based on differences in the etching rates of different crystallographic planes. Silicon, for example, has a diamond structure, shown in FIG. 2. The crystal habit of silicon is face-centered cubic. The overall packing density of the silicon lattice is 34%. The silicon crystalline structure shows that the packing density differs in each crystallographic plane. For example, cutting the silicon unit cell along different planes will give the molecular bonding structure shown in FIG. 3. The (111) planes have a higher packing density than the (100) and (110) planes. The packing densities influence the etch rate because there are more atoms to remove in the more closely packed configurations.

In the etching process a chemical reaction occurs that breaks the covalent bonds between the atoms on the surface (etch front) and their neighboring atoms. In an anisotropic etch, different crystalline planes are etched at different rates. There are two main factors that affect the etch rate: the number of atoms to be removed, and the number of covalent bonds that are needed to be broken to remove the atoms. The two planes of interest in the design of templates in accordance with the present invention are the (111) and (100) planes. FIG. 4 shows the different etch fronts of these planes.

The etch front atom in the (100) plane is located on the face of the crystalline plane (located at [1,½,½]), and the etch front atom of the (111) plane is located on the diagonal (located at [¼,¼,¾]). Removing an etch front atom in the (111) plane would require the breaking of three covalent bonds, whereas the (100) plane would only require two bond ruptures. The number of bonds to be broken is directly related to how much energy will be required to cause the atom to be removed from the surface. This demonstrates how the selectivity of an anisotropic etch can be achieved when the bonding strength of the etch front atoms are compared. These differences allows the achievement of differences in the etching rates of the (100) and (111) planes on the order of 100:1.

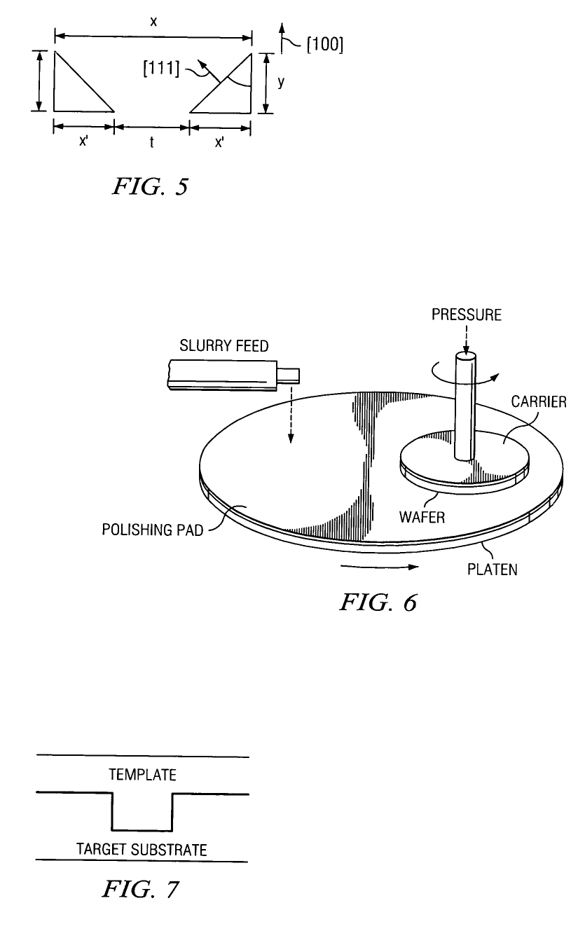

The cross section of a hole etched in a template in accordance with the present invention is shown in FIG. 5. \vec{a} is the unit vector in the [111] plane, \vec{b} is the unit vector in the [100] plane and θ is the angle between the planes. The derivation below can be used to calculate the angle of the grooves formed in the template by anisotropic etching. The calculation below uses the dot product to solve for 0.

$$\vec{a} \cdot \vec{b} = \vert \vec{a} \vert \cdot \vert \vec{b} \vert \cdot cos ( θ ) ⇔ cos ( {θ}_{O} = \frac{\vec{a} \cdot \vec{b}}{\vert \vec{a} \vert \cdot \vert \vec{b} \vert} = \frac{1}{\sqrt{3}} ⇒ θ = {cos}^{- 1} ( \frac{1}{\sqrt{3}} ) = {54.74}^{∘}$$

With the physical dimensions of a hole, for example, being known, the following calculations may be preformed to determine the size of the nanowire or dot that will be formed. FIG. 5 depicts the variables that are used for the nano structure definition.

The thickness of the template, y, is chosen to give mechanical strength to the wafer. X is the width of the pattern to be defined by photolithography on the template; t is the target width that will set the nano-structure dimensions.

$$\begin{matrix}x = 2 {x}^{′} + t \\ tan θ = \frac{y}{{x}^{′}} ⇒ {x}^{′} = \frac{y}{tan θ} \\ ⇒ x = 2 ( \frac{y}{tan θ} ) + t\end{matrix} \qquad ( 1 )$$

Equation 1 may be used to define a nano-scale pattern on the target substrate by determining the necessary thickness and pattern size on the template. The pattern on the template surface may be defined by photolithography or other masking methods. The method may be, for example, contact printing. Contact printing offers high-resolution capabilities and the small error. Due to the design of the template any error can be introduced when transferring the pattern from the template to the target substrate. Caution should be taken during the pattern transfer, since any error that is introduced will directly correlate to a distortion in the size and shape of the nano-structure.

The photoresist used in the pattern transfer is selected based on its resolution capabilities, which should help minimize the error that is introduced. Other issues related to the photolithography process include errors in alignment of the mask (rotational or translational). The thermal run-in/run-out error also be considered to minimize the error introduced by thermal issues. The thermal run-in (run-out) is the shift in the transferred pattern due to the small variations of the mask and/or wafer dimensions. If the lithography process is conducted in a temperature-varying environment, the wafer and the mask will stretch. Since they have different coefficients of thermal expansion (CTE), it will cause a shift in the mask pattern. Equation 2 shows the relationship for thermal run-out.

R=r.(ΔTₘ.αₘ−ΔTₛᵢ.αₛᵢ) (2)

Where ΔTₘ, ΔTₛᵢ are the changes in the mask and silicon wafer temperatures, and αₘ, αsi is the coefficient of thermal expansion of the mask and silicon wafer. Conducting the process in a temperature-controlled environment will minimize the thermal run-out error.

The surface topology of the template can also generate errors in the transferred pattern. The mask may not lay perfectly flat on the surface of the wafer due to small imperfections, and therefore cause the light to strike the photoresist at an angle. The transferred pattern would then be skewed from its desired form. Chemical Mechanical Polishing (CMP) of the wafer surface will reduce the roughness of the template wafer and allow for creating the desired patterns. The CMP process is illustrated in FIG. 6.

Two processes take place during CMP to polish and smooth the surface of the wafer. The first step uses a chemical reaction between the slurry that is applied and the surface of the wafer. The second polishing mechanism is the mechanical interaction between the pad and the film. Both processes cause the atoms to be released from the surface by breaking the chemical bonds between the atoms.

An additional step that may be used in creation of a template in accordance with the present invention is to etch alignment markers on the target wafer and template. One possible representation of the alignment marks is shown in FIG. 7, where a notch on the template is placed in a void in the target. Alternative orientations of alignment features and alternative methods of alignment may be used. Examples of alternatives include the reversal of the alignment features in FIG. 7, i.e. placing a notch on the target into a void in the template, or using optical alignment in place of physical methods.

Several deposition techniques may be used with the present invention. Four examples of techniques are described, and are depicted in FIG. 9. The first example is a direct deposition technique. This process will involve the template being placed, for example, directly on the target substrate and then fabricating the nano structures using a deposition process such as chemical vapor deposition (CVD), molecular beam epitaxy (MBE), or sputtering.

Nanospray technology may also be used to deposit material through a template of the present invention. The nano spray technique uses a high voltage placed on the template. The ionization of the target molecule occurs as the molecule passes through the template. The electric field developed on the template will intensify around the openings produced in the template due to edge effects. As the molecules pass through the opening the field will be strong enough to remove an electron. The repulsive force that will be created between the ion and the template will then force the ion through the hole onto the target substrate. A negative potential may be placed on the target substrate to attract the target ion as it passes through the template.

A second ion-assisted deposition technique that may be used with the present invention uses a radio frequency potential to ionize the molecules that are to be deposited. Once the ions have been formed, a negative potential will be applied to the target substrate to direct the ions as they pass through the template. Altering the CVD, MBE or sputtering process to allow for control voltages to be applied to the surface of the target substrate or template may also be used with the present invention.

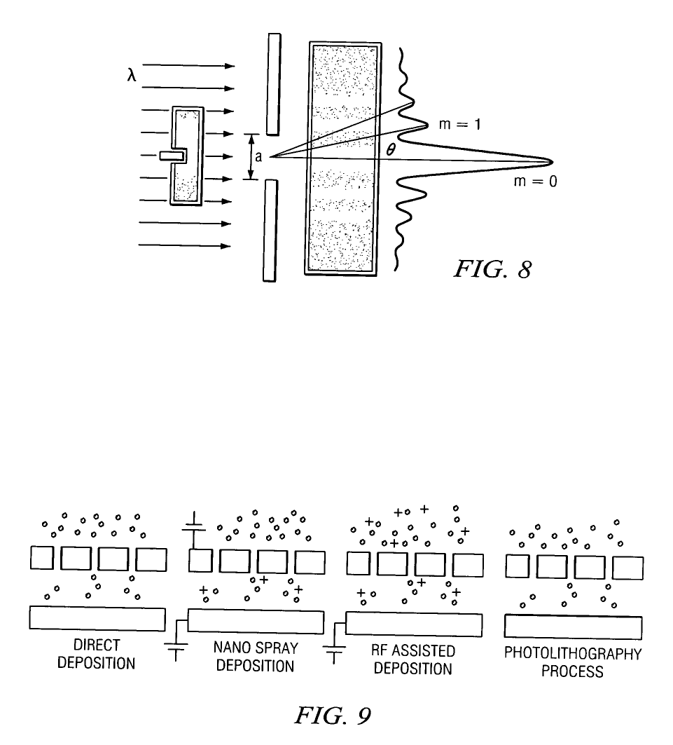

Another process that may be used is a lift-off fabrication procedure. This process uses a thin layer of photoresist placed on the target substrate. The template is then placed on top of the target substrate and both are placed in a photolithography machine. The template acts like a mask and causes the exposure of only small areas of the photoresist. The photoresist can then be developed and removed to allow for a deposition process. Once a material has been deposited, the remaining photoresist will be lifted off to form the desired nano structures. Due to the ionization, light passing through a slit in the template will produce an interference pattern that will be developed on the photoresist. Keeping the template close to the target substrate by using a very thin film of photoresist minimizes the width of the primary node in the interference pattern formed. By using a lower power source the intensity of the signal applied to the photoresist will decrease faster in the primary node of the interference pattern thereby decreasing its width. The interference pattern that can be obtained from the template is shown in FIG. 8.

Equations 3 and 4 show the relationship for destructive interference and intensity for FIG. 8.

$$\begin{matrix}sin θ = m \frac{λ}{a} & ( 3 ) \\ {I}_{θ} = {{I}_{0} [ \frac{sin ( π a sin ( θ / λ )}{π a sin ( θ / λ )} ]}^{2} & ( 4 )\end{matrix}$$

Although preferred embodiments of the present invention have been described in detail herein, those skilled in the art will recognize that various substitutions and modifications may be made to the invention without departing from the scope and spirit of the appended claims.

What is claimed is:

1. A method for forming a template for use in fabricating sub-micron scale features comprising the steps of:
determining a pattern for a template;
calculating the required thickness of a crystalline template substrate, having an upper surface and a lower surface, to produce the template pattern in the substrate;
creating a mask corresponding to the pattern;
contacting the mask with the upper surface of the crystalline template substrate; and
anisotropically etching the upper surface of the crystalline substrate with an etchant to produce a template with openings in the bottom surface of the substrate essentially corresponding with the pattern.

2. The method of claim 1, wherein the template comprises substantially circular openings.

3. The method of claim 1, wherein the template comprises linear openings.

4. The method of claim 1, wherein the template comprises a combination of two or more shapes of openings.

5. The method of claim 1, further comprising the steps of calculating the time for the etchant to etch the thickness of the template substrate, and removing the etchant after such time.

6. The method of claim 1, wherein the crystalline template substrate is silicon.

7. The method of claim 1, wherein the template substrate is a material with a face-centered cubic crystal habit.

8. The method of claim 1, wherein the etchant comprises hydrogen fluoride.

9. The method of claim 7, wherein the etching occurs in a direction essentially in the [100] plane of the template substrate.

10. The method of claim 1, wherein the steps of creating a mask and contacting the mask with the substrate are accomplished simultaneously through the use of a photolithographic technique.

11. A method of fabricating sub-micron scale features comprising the steps of:
determining a pattern for a template;
creating a mask corresponding to the pattern;
calculating the required thickness of a crystalline template substrate, having an upper surface and a lower surface, to produce the template pattern in the substrate;
contacting the mask with the upper surface of the crystalline template substrate;
anisotropically etching the upper surface of the crystalline substrate with an etchant to produce a template with openings in the bottom surface of the substrate essentially corresponding with the pattern;
aligning the template with a target; and
depositing material through the template to substantially reproduce pattern on the on the surface of the target.

12. The method of claim 1, wherein the template comprises substantially circular openings.

13. The method of claim 11, wherein the template comprises linear openings.

14. The method of claim 11, wherein the template comprises a combination of two or more shapes of openings.

15. The method of claim 11, further comprising the steps of calculating the time for the etchant to etch the thickness of the template substrate, and removing the etchant after such time.

16. The method of claim 11, wherein the crystalline template substrate is silicon.

17. The method of claim 11, wherein the template substrate is a material with a face-centered cubic crystal habit.

18. The method of claim 17, wherein the etching occurs in a direction essentially in the [100] plane of the template substrate.

19. The method of claim 11, wherein the etchant comprises hydrogen fluoride.

20. The method of claim 11, wherein the alignment is accomplished with by inserting alignment feature on the template into a void on the substrate.

21. The method of claim 11, wherein the alignment includes placing the template in direct contact with the substrate.

22. The method of claim 11, wherein the deposition is accomplished by chemical vapor deposition through the template.

23. The method of claim 10, wherein the deposition is accomplished by molecular beam epitaxy through the template.

24. The method of claim 10, wherein the deposition is accomplished via nanospray deposition through the template.

25. The method of claim 10, wherein the deposition is accomplished via ion assisted deposition through the template.

26. The method of claim 10, wherein a layer of photoresist is placed on the substrate and exposed to light through the template.

27. The method of claim 1, wherein the steps of creating a mask and contacting the mask with the substrate are accomplished simultaneously through the use of a lithographic technique.
